(19) United States
(12) Patent Application Publication
(10) Pub. No.: US 2026/0323921 A1
(43) Pub. Date: Oct. 15, 2026

(54) SEMICONDUCTOR DEVICE

(71) Applicant: Kioxia Corporation, Tokyo (JP)

(72) Inventors: Takeshi AOKI, Ebina Kanagawa (JP); Takayuki MIYAZAKI, Setagaya Tokyo (JP); Masaharu WADA, Yokohama Kanagawa (JP); Takashi INUKAI, Yokohama Kanagawa (JP)

(21) Appl. No.: 19/720,316

(22) Filed: Jun. 25, 2026

Related U.S. Application Data
(62) Division of application No. 18/448,703, filed on Aug. 11, 2023.

(30) Foreign Application Priority Data
Aug. 12, 2022 (JP) 2022-128883

(51) Int. Cl. H10B 12/00; H10D 30/67

(52) U.S. Cl. CPC H10B 12/33; H10B 12/48; H10D 30/6728; H10D 30/6755

(57) ABSTRACT

According to one embodiment, a semiconductor device includes a semiconductor substrate and a capacitor that includes a first electrode extending in a first direction intersecting the semiconductor substrate and a second electrode facing the first electrode. A first conductive layer is above the capacitor and extends in a second direction. A semiconductor layer penetrates the first conductive layer in the first direction. A first conductor can be above or below the first conductive layer and electrically connected to the first conductive layer. A first insulating film is between the first conductive layer and the semiconductor layer. A second conductive layer extends in the second direction and is electrically connected to the first conductive layer via the first conductor.

### CROSS-REFERENCE TO RELATED APPLICATIONS

This application is a division of U.S. patent application Ser. No. 18/448,703, filed Aug. 11, 2023, which is based upon and claims the benefit of priority from Japanese Patent Application No. 2022-128883, filed Aug. 12, 2022, the entire contents of each of which are incorporated herein by reference.

### FIELD

Embodiments described herein relate generally to a semiconductor device.

### BACKGROUND

A semiconductor memory device including bit lines, word lines, and memory cells (transistors and capacitors) connected thereto is used. By selecting a bit line and a word line and applying a voltage, data can be written to and read from a memory cell.

### BRIEF DESCRIPTION OF THE DRAWINGS

FIG. 1 is a circuit diagram of a memory cell array.

FIG. 2 is a schematic plan view of a memory cell array.

FIG. 3 is a schematic cross-sectional view of a memory cell array.

FIG. 4 is a schematic plan view of a memory cell array.

FIG. 5 is a schematic cross-sectional view of a memory cell array.

FIGS. 6 to 19 are schematic cross-sectional views illustrating aspects of a manufacturing method of a memory cell array.

FIG. 20A is a schematic cross-sectional view illustrating another example of a memory cell array.

FIG. 20B is a schematic cross-sectional view illustrating another example of a memory cell array.

FIG. 21 is a schematic plan view illustrating another example of a memory cell array.

FIG. 22 is a schematic plan view illustrating another example of a memory cell array.

FIG. 23 is a schematic plan view illustrating another example of a memory cell array.

FIG. 24 is a schematic cross-sectional view illustrating a modification of a memory cell array.

FIGS. 25 to 31 are schematic cross-sectional views illustrating aspects of a manufacturing method of a modification of a memory cell array.

FIG. 32 is a schematic plan view illustrating a second structural example of a memory cell array.

FIG. 33 is a schematic cross-sectional view illustrating the second structural example of a memory cell array.

FIGS. 34 to 42 are schematic cross-sectional views illustrating aspects of a manufacturing method of the second structural example.

### DETAILED DESCRIPTION

Embodiments are to prevent deterioration in reliability otherwise accompanying miniaturization of a semiconductor device.

In general, according to one embodiment, a semiconductor device includes a semiconductor substrate and a capacitor above the semiconductor substrate. The capacitor extends in a first direction and includes a first electrode and a second electrode facing the first electrode. A first conductive layer is above the capacitor in the first direction and extends in a second direction intersecting the first direction. A semiconductor layer penetrates the first conductive layer in the first direction and is electrically connected to the first electrode. A first conductor can be above or below the first conductive layer in the first direction. The first conductor is electrically connected to the first conductive layer. A first insulating film is between the first conductive layer and the semiconductor layer. A second conductive layer extends in the second direction and is electrically connected to the first conductive layer via the first conductor.

Hereinafter, certain example embodiments will be described with reference to the drawings. The depicted relationships between the thicknesses and other dimensions of each component in the drawings, the ratio of the dimensions of each component, and the like may differ from actual ones. The vertical direction may differ from the vertical direction according to gravitational acceleration. In the embodiments, substantially the same components are denoted by the same reference symbols, and the descriptions thereof may be omitted as appropriate from subsequent embodiments or examples.

In the specification, “connection” includes not only physical connection but also electrical connection, and, unless otherwise specified, includes not only direct connection but also indirect connection.

A semiconductor device according to an embodiment is a dynamic random access memory (DRAM) and includes a memory cell array.

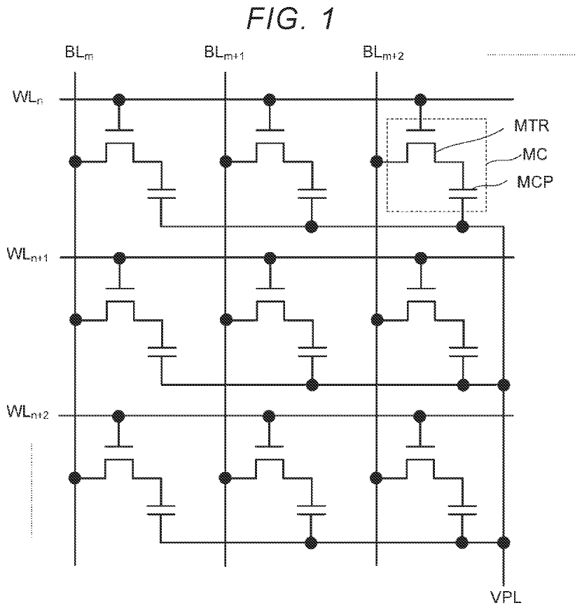

FIG. 1 is a circuit diagram illustrating a circuit configuration example of a memory cell array. In FIG. 1, a plurality of memory cells MC, a plurality of word lines WL (word line WLₙ, word line WLₙ₊₁, word line WLₙ₊₂, n is an integer), and a plurality of bit lines BL (bit line BLₘ, bit line BLₘ₊₁, bit line BLₘ₊₂, m is an integer), and a power supply line VPL are illustrated.

A plurality of memory cells MC is located in rows and columns to form a memory cell array. Each memory cell MC includes a memory transistor MTR which is a field effect transistor (FET), and a memory capacitor MCP. A gate of the memory transistor MTR is connected to the corresponding word line WL, and one of a source and a drain is connected to the corresponding bit line BL. The word line WL is connected to a row decoder, for example. The bit line BL is connected to a sense amplifier, for example. A first electrode of the memory capacitor MCP is connected to the other of the source and drain of the memory transistor MTR, and a second electrode is connected to the power supply line VPL that supplies a specific potential. The power supply line VPL is connected to a power supply circuit. The memory cell MC can store data by accumulating charges from the bit line BL to the memory capacitor MCP by switching the memory transistor MTR by the word line WL. The number of memory cells MC is not limited to the number illustrated in FIG. 1.

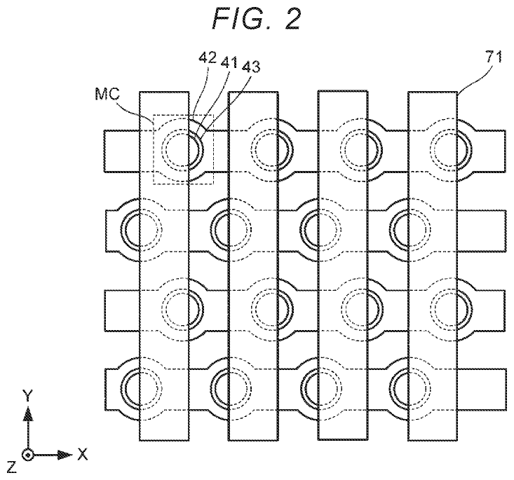

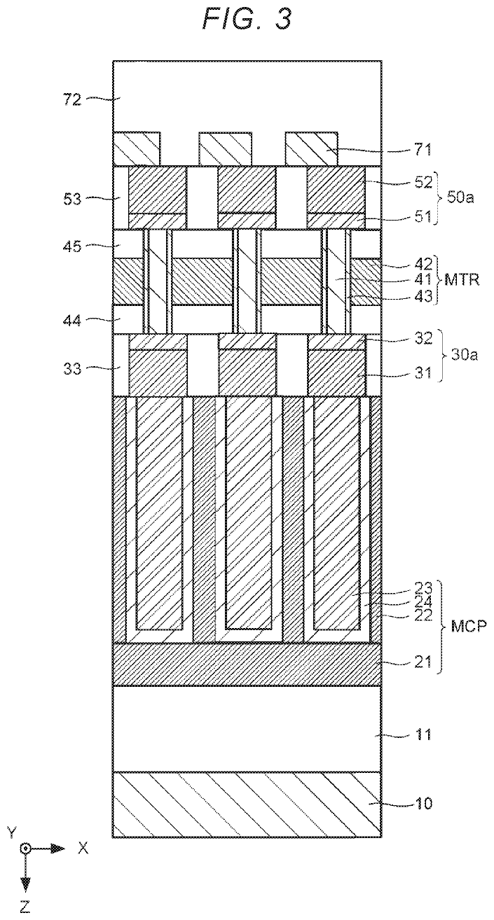

FIG. 2 is a schematic plan view illustrating a structural example of a memory cell array. FIG. 3 is a schematic cross-sectional view illustrating the structural example of the memory cell array. The Z-axis is a direction intersecting the surface of a semiconductor substrate 10. FIG. 2 illustrates a part of the X-Y plane. FIG. 3 illustrates a part of the X-Z cross-section.

The memory cell array includes a conductor 21, a conductive layer 22, an electrical conductor 23, an insulator 24, a conductive layer 31, a conductive oxide layer 32, an oxide semiconductor layer 41, a conductive layer 42, an insulating film 43, a conductive oxide layer 51, a conductive layer 52, and a conductive layer 71. FIG. 2 illustrates the oxide semiconductor layer 41, the conductive layer 42, the insulating film 43, and the conductive layer 71 for convenience, and the illustration of other components is omitted for convenience.

The memory transistor MTR and the memory capacitor MCP are provided above an insulating layer 11 on the semiconductor substrate 10, as illustrated in FIG. 3. A peripheral circuit such as a row decoder, a sense amplifier, and a power supply circuit are formed on the semiconductor substrate 10. The peripheral circuit includes field effect transistors such as a P-channel field effect transistor (Pch-FET) and an N-channel field effect transistor (Nch-FET). The field effect transistor can be formed using the semiconductor substrate 10 such as a single crystal silicon substrate, and the Pch-FET and the Nch-FET have a channel region, a source region, and a drain region in the semiconductor substrate 10. The semiconductor substrate 10 may have P-type conductivity. The insulating layer 11 is provided on the semiconductor substrate 10 and comprises, for example, silicon (Si) and oxygen (O) or silicon (Si) and nitrogen (N). The insulating layer 11 may be a stacked film.

The conductor 21, the conductive layer 22, the electrical conductor 23, and the insulator 24 form the memory capacitor MCP. The memory capacitor MCP is a three-dimensional capacitor such as a so-called pillar type capacitor or cylinder type capacitor.

The conductor 21 is provided above the semiconductor substrate 10 with the insulating layer 11 interposed therebetween. The conductive layer 22 is provided on a part of the conductor 21. The conductor 21 and the conductive layer 22 form a second electrode of the memory capacitor MCP. The conductor 21 extends to overlap with a plurality of electrical conductors 23 when viewed from the Z-axis direction. The conductor 21 is also called a plate electrode. The electrical conductor 23 is provided above the conductor 21 with the insulator 24 interposed therebetween, extends in the Z-axis direction, and forms a first electrode of the memory capacitor MCP. The insulator 24 is provided between the conductor 21 and the conductive layer 22, and the electrical conductor 23 to form the dielectric of the memory capacitor MCP.

The conductor 21 and the conductive layer 22 comprise materials such as tungsten and titanium nitride. The electrical conductor 23 comprises materials such as tungsten, titanium nitride, or amorphous silicon. The insulator 24 comprises materials such as hafnium oxide, zirconium oxide, or aluminum oxide.

The conductive layer 31 is provided on the electrical conductor 23 and electrically connected to the electrical conductor 23. The conductive layer 31 comprises, for example, copper. The conductive layer 31 may not be formed.

The conductive oxide layer 32 is provided on the conductive layer 31. The conductive oxide layer 32 comprises metal oxide such as indium-tin-oxide (ITO).

The conductive layer 31 and the conductive oxide layer 32 form a conductor 30a. A plurality of conductors 30a are provided corresponding to the plurality of electrical conductors 23. An insulating layer 33 is formed between the plurality of conductors 30a. The insulating layer 33 comprises, for example, silicon and oxygen or silicon nitrogen.

The oxide semiconductor layer 41, the conductive layer 42, and the insulating film 43 form the memory transistor MTR. The memory transistor MTR is provided above the memory capacitor MCP. A plurality of memory transistors MTR is provided corresponding to a plurality of memory capacitors MCP. An insulating layer 44 and an insulating layer 45 are formed between the plurality of memory transistors MTR. The insulating layer 44 and the insulating layer 45 comprise, for example, silicon and oxygen or silicon and nitrogen.

The oxide semiconductor layer 41 is, for example, a columnar body extending in the Z-axis direction. The oxide semiconductor layer 41 penetrates the conductive layer 42 in the Z-axis direction. The oxide semiconductor layer 41 forms a channel of the memory transistor MTR. The oxide semiconductor layer 41 comprises indium (In), for example. The oxide semiconductor layer 41 comprises, for example, indium oxide and gallium oxide, indium oxide and zinc oxide, or indium oxide and tin oxide. An example includes an oxide containing indium, gallium, and zinc (indium-gallium-zinc-oxide), a so-called IGZO (InGaZnO).

One end of the oxide semiconductor layer 41 in the Z-axis direction is connected to the conductive layer 31 via the conductive oxide layer 32 and functions as the other of the source and drain of the memory transistor MTR. The conductive oxide layer 32 is provided between the electrical conductor 23 of the memory capacitor MCP and the oxide semiconductor layer 41 of the memory transistor MTR, and functions as the other of the source electrode and the drain electrode of the memory transistor MTR. Since the conductive oxide layer 32 comprises metal oxide similarly to the oxide semiconductor layer 41 of the memory transistor MTR, the connection resistance between the memory transistor MTR and the memory capacitor MCP can be reduced.

The conductive layer 42 includes a portion facing the oxide semiconductor layer 41 with the insulating film 43 interposed therebetween in the X-Y plane. The conductive layer 42 forms a gate electrode of the memory transistor MTR and forms the word line WL as a wiring. The conductive layer 42 comprises a metal, a metal compound, or a semiconductor. The conductive layer 42 comprises at least one material selected from a group consisting of tungsten (W), titanium (Ti), titanium nitride (TiN), molybdenum (Mo), cobalt (Co), and ruthenium (Ru), for example.

In FIG. 2, the conductive layer 42 has a narrower width in the Y-axis direction in a region that does not overlap with the memory transistor MTR than in a region that overlaps with the memory transistor MTR when viewed in the Y-axis direction. The width of the conductive layer in the Y-axis direction is not limited thereto and may be a constant value.

As illustrated in FIG. 2, the plurality of conductive layers 42 extend in the X-axis direction and are located parallel to each other. Each conductive layer 42 is overlapped and connected to a plurality of memory cells MC in the X-axis direction.

The insulating film 43 is provided between the oxide semiconductor layer 41 and the conductive layer 42 on the X-Y plane. The insulating film 43 forms a gate insulating film of the memory transistor MTR. The insulating film 43 comprises, for example, silicon and oxygen or silicon and nitrogen.

The memory transistor MTR is a so-called surrounding gate transistor (SGT) in which a gate electrode surrounds a channel. The SGT can reduce an area of the semiconductor device.

A field effect transistor including a channel layer comprising an oxide semiconductor has a lower off-leakage current than a field effect transistor provided on the semiconductor substrate 10. Therefore, the data stored in the memory cell MC can be stored for a long time, so the number of refresh operations can be reduced. Since the field effect transistor including the channel layer containing the oxide semiconductor can be formed by a low-temperature process, application of thermal stress to the memory capacitor MCP can be prevented.

The conductive oxide layer 51 is provided on the oxide semiconductor layer 41. The conductive oxide layer 51 comprises a metal oxide such as indium-tin-oxide (ITO).

The conductive layer 52 is provided on the conductive oxide layer 51 and electrically connected to the conductive oxide layer 51. The conductive layer 52 comprises, for example, copper.

The conductive oxide layer 51 and the conductive layer 52 form a conductor 50a. The conductor 50a is electrically connected to a sense amplifier via a bit line BL. The conductor 50a functions as a conductive pad for connecting the memory transistor MTR and the bit line BL, for example. A plurality of conductors 50a are provided corresponding to a plurality of memory transistors MTR. An insulating layer 53 is formed between the plurality of conductors 50a. The insulating layer 53 comprises, for example, silicon and oxygen or silicon nitrogen.

The other end of the oxide semiconductor layer 41 in the Z-axis direction is connected to the conductive layer 52 via the conductive oxide layer 51 and functions as one of the source or drain of the memory transistor MTR. The conductive oxide layer 51 functions as one of the source electrode or the drain electrode of the memory transistor MTR. Since the conductive oxide layer 51 comprises a metal oxide, similarly to the oxide semiconductor layer 41 of the memory transistor MTR, the connection resistance between the memory transistor MTR and the bit line BL can be reduced.

The conductive layer 71 is provided on the conductive layer 52 and connected to the conductor 50a. The conductive layer 71 forms the bit line BL as a wiring. An insulating layer 72 is formed between the plurality of conductive layers 71. The insulating layer 72 comprises, for example, silicon and oxygen or silicon and nitrogen.

The plurality of conductive layers 71 (bit lines BL) extend in the Y-axis direction and are located parallel to each other, as illustrated in FIG. 2. Each conductive layer 71 is overlapped and connected to a plurality of memory cells MC when viewed from the Z-axis direction.

A plurality of memory cells MC forms a staggered arrangement on the X-Y plane, as illustrated in FIG. 2. The memory cell MC connected to one of a plurality of word lines WL is located shifted in the X-axis direction with respect to the memory cell MC connected to the adjacent word line WL. Thereby, the degree of integration of the memory cell MC can be increased.

As the memory cell MC is miniaturized, for example, the wiring width (the width in the Y-axis direction) of the word line WL may be narrowed. However, in the structures illustrated in FIGS. 2 and 3, if the wiring width of the word lines WL is narrowed, the wiring resistance increases particularly in the memory cell MC portion due to the fine line effect. The fine line effect causes decrease in reliability of the semiconductor device.

Although the memory capacitor MCP needs to connect the plate electrode to the power supply line VPL, the plate electrode is required to be connected to the power supply line VPL at the end of the memory cell array, and thus, it is difficult to prevent noise of the plate electrode. A response speed of the power supply circuit connected to the power supply line VPL slows down as a load capacity of the plate electrode increases. This becomes remarkable as the power consumption of the power supply circuit is reduced. This also causes deterioration in the reliability of the semiconductor device.

A semiconductor device of an embodiment includes an auxiliary wiring provided in a layer different from that of the word line WL. The auxiliary wiring is electrically connected to the word line WL via a conductor provided in the memory cell array. The auxiliary wiring will decrease the wiring resistance of the word line WL.

Another semiconductor device of the embodiment includes the power supply line VPL provided above the memory cell array and electrically connected to the plate electrode via a conductor provided in the memory cell array. Such configuration will reduce noise to the plate electrode.

Specific structural examples of the semiconductor devices of the embodiments will be described below.

### First Structural Example of Memory Cell Array

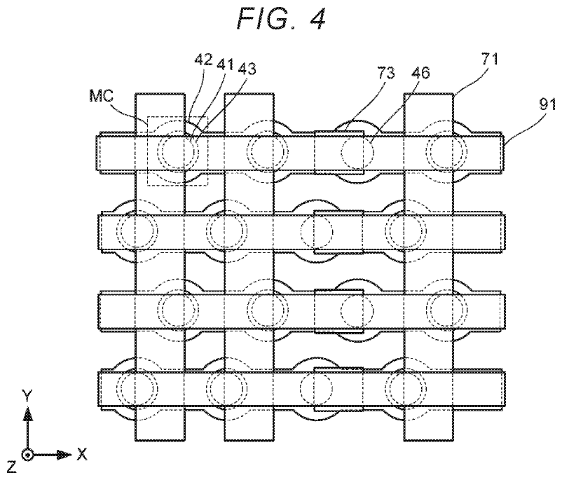

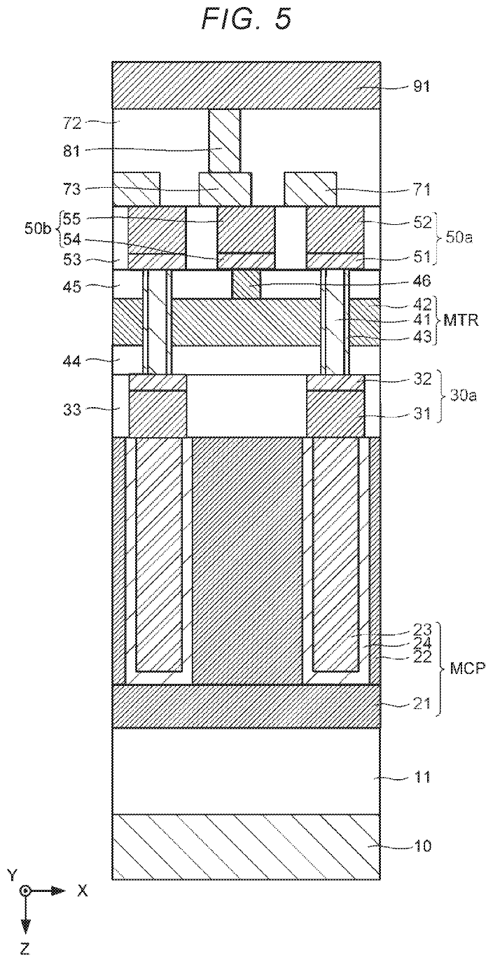

FIG. 4 is a schematic plan view illustrating a first structural example of the memory cell array. FIG. 5 is a schematic cross-sectional view illustrating the first structural example of the memory cell array. FIG. 4 illustrates a part of the X-Y plane. FIG. 5 illustrates a part of the X-Z cross-section. In the following, the portions different from FIGS. 2 and 3 are described, and the descriptions of FIGS. 2 and 3 can be used as appropriate for other portions.

The first structural example of the memory cell array further includes a conductor 46, a conductive oxide layer 54, a conductive layer 55, a conductive layer 73, a conductor 81, and a conductive layer 91. FIG. 4 illustrates the oxide semiconductor layer 41, the conductive layer 42, the insulating film 43, the conductor 46, the conductive layer 71, the conductive layer 73, and the conductive layer 91 for convenience, and the illustration of other components is omitted for convenience.

The conductors 46 are provided between a plurality of memory cells MC in the X-axis direction. The conductor 46 is provided on the conductive layer 42. Above and below the conductor 46, as illustrated in FIG. 5, the memory transistor MTR and the memory capacitor MCP are not formed. FIG. 4 illustrates a plurality of conductors 46 provided corresponding to the plurality of conductive layers 42. A plurality of conductors 46 form a staggered arrangement together with a plurality of memory cells MC. The conductor 46 comprises, for example, a material applicable to the conductive layer 42.

The conductive oxide layer 54 is provided on the conductor 46 and electrically connected to the conductor 46. The conductive oxide layer 54 comprises, for example, a material applicable to the conductive oxide layer 51.

The conductive layer 55 is provided on the conductive oxide layer 54 and electrically connected to the conductive oxide layer 54. The conductive layer 55 includes, for example, a material applicable to the conductive layer 52. In some examples, one of the conductive oxide layer 54 or the conductive layer 55 may not be provided.

The conductive oxide layer 54 and the conductive layer 55 form a conductor 50b. A plurality of conductors 50b are provided corresponding to the plurality of conductive layers 42. The insulating layer 53 is formed between the plurality of conductors 50b and between the conductors 50a and the conductors 50b.

As illustrated in FIG. 4, the conductive layer 73 is provided between the plurality of memory cells MC when viewed from the Z-axis direction and is connected to the conductor 46 via one of the conductors 50a. The conductive layer 73 is provided in the same layer as the conductive layer 71 and is provided over the conductive layer 55. The conductive layer 73 functions as a conductive pad. The conductive layer 73 includes a material that is applicable to the conductive layer 71. A plurality of conductive layers 73 are provided corresponding to the plurality of conductive layers 42. The insulating layer 72 is formed between the plurality of conductive layers 73 and between the conductive layer 71 and the conductive layer 73.

The conductor 81 is provided on the conductive layer 73 and extends in the insulating layer 72 in the Z-axis direction. The conductor 81 electrically connects the conductive layer 91 and the conductive layer 73. The conductor 81 comprises copper, for example. A plurality of conductors 81 are provided corresponding to the plurality of conductive layers 73. The insulating layer 72 is formed between the plurality of conductors 81.

The conductive layer 91 is provided on the conductor 81 and the insulating layer 72 and extends in the X-axis direction as illustrated in FIG. 4. The conductive layer 91 forms the auxiliary wiring for the word line WL. The conductive layer 91 comprises, for example, a metal, a metal compound, or a semiconductor. The conductive layer 91 comprises, for example, at least one material selected from a group consisting of tungsten, titanium, titanium nitride, molybdenum, cobalt, and ruthenium. A plurality of conductive layers 91 are provided corresponding to the plurality of conductive layers 42. An insulating layer may be formed between the plurality of conductive layers 91.

As described above, in the first structural example, the conductive layer 91 is formed above the plurality of memory cells MC. By electrically connecting the conductive layer 42 and the conductive layer 91 via the conductor 46, the conductor 50b, the conductive layer 73, and the conductor 81, the increase in the wiring resistance can be reduced even if the wiring width of the word line WL is narrowed. As a result, it is possible to reduce deterioration in reliability due to miniaturization of the semiconductor device.

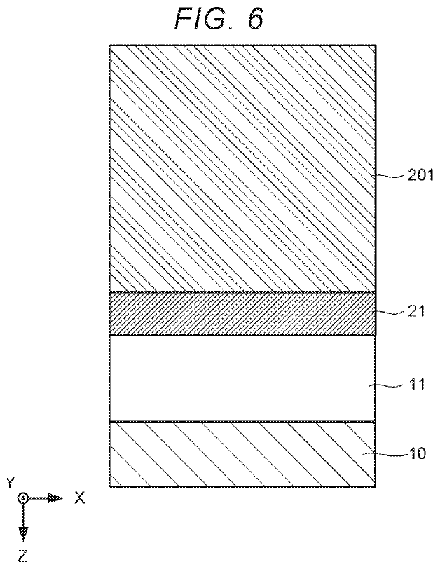

Next, an example of a manufacturing method of the first structural example will be described with reference to FIGS. 6 to 19. FIGS. 6 to 19 are schematic cross-sectional views illustrating an example of the manufacturing method of the first structural example. FIGS. 6 to 19 illustrate a part of the X-Z cross-section. Here, a manufacturing process from forming the peripheral circuit to forming the memory cell array will be described.

As illustrated in FIG. 6, the conductor 21 is formed on the insulating layer 11 on the semiconductor substrate 10 and an insulating layer 201 is formed on the conductor 21. The conductor 21 can be formed by, for example, forming a conductive film using sputtering or ALD and then partially removing the conductive film by etching using a resist mask, for example. The insulating layer 201 comprises, for example, silicon and nitrogen. The insulating layer 201 can be formed using chemical vapor deposition (CVD) or coating, for example.

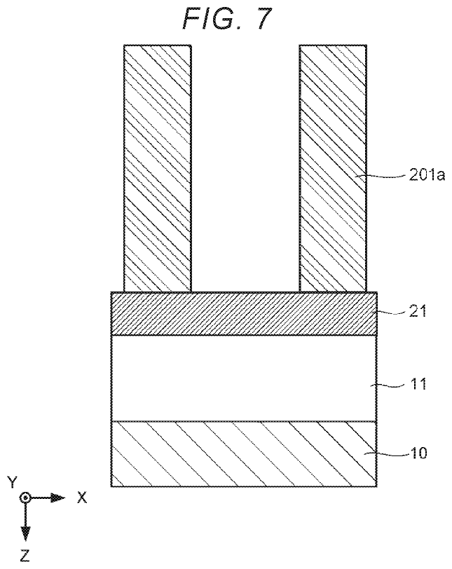

Next, as illustrated in FIG. 7, the insulating layer 201 is partially removed to partially expose the upper surface of the conductor 21, and then leave a plurality of portions 201a where the electrical conductor 23 and the insulator 24 will be formed. The insulating layer 201 can be partially removed by etching using a resist mask, for example.

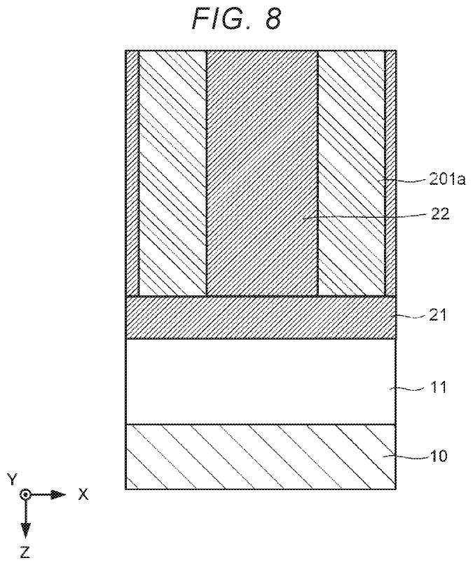

Next, as illustrated in FIG. 8, the conductive layer 22 is formed on the conductor 21, and the conductive layer 22 is partially removed in the thickness direction to expose the upper surfaces of the plurality of portions 201a. As a result, the conductive layer 22 remains between the plurality of portions 201a. The conductive layer 22 can be formed using, for example, sputtering or atomic layer deposition (ALD). The conductive layer 22 can be partially removed by, for example, reactive ion etching (RIE) or chemical mechanical polishing (CMP).

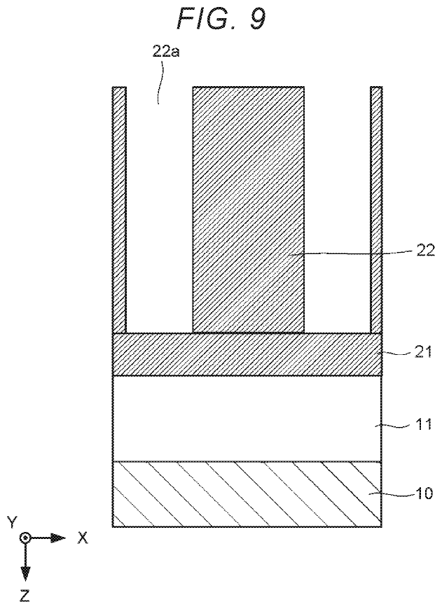

Next, as illustrated in FIG. 9, the plurality of portions 201a are removed to form openings 22a penetrating the conductive layer 22 in the Z-axis direction. The portion 201a can be removed, for example, by etching.

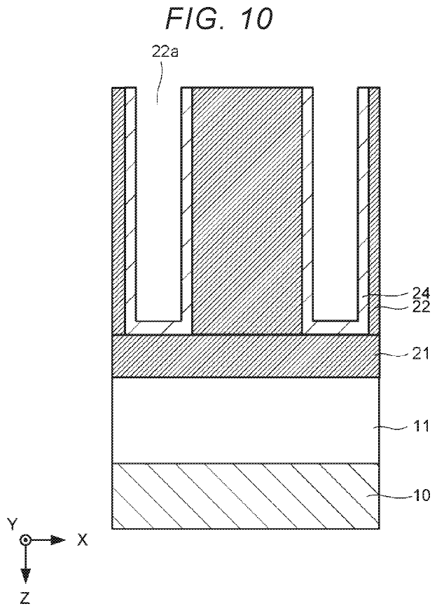

Next, the insulator 24 is formed on the conductive layer 22 and is partially removed in the thickness direction to expose the upper surface of the conductive layer 22. Thereby, as illustrated in FIG. 10, the insulator 24 remains on the inner surface of the opening 22a. The insulator 24 can be formed using CVD or ALD, for example.

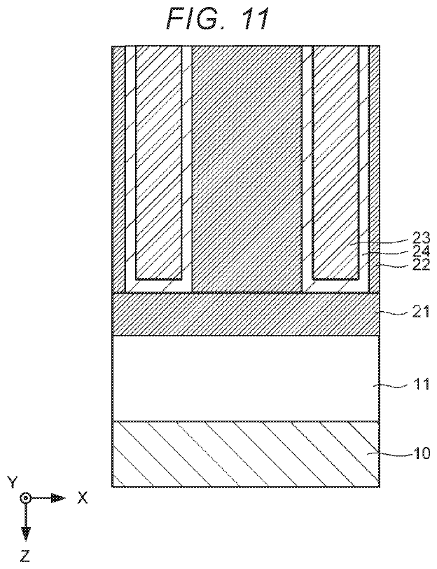

Next, the electrical conductor 23 is formed on the conductive layer 22 and the insulator 24, and the electrical conductor 23 is partially removed in the thickness direction to expose the upper surface of the conductive layer 22. Thereby, as illustrated in FIG. 11, the electrical conductor 23 remains inside the opening 22a. The electrical conductor 23 can be formed using, for example, sputtering or ALD. The electrical conductor 23 can be partially removed by, for example, RIE or CMP.

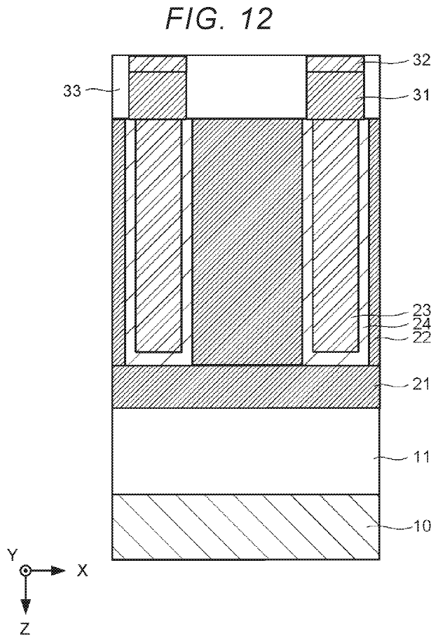

Next, as illustrated in FIG. 12, the conductive layer 31, the conductive oxide layer 32, and the insulating layer 33 are formed. The conductive layer 31 and the conductive oxide layer 32 can be formed by, for example, forming a stacked film using sputtering or ALD, and then partially removing the stacked film by etching using a resist mask, for example. The insulating layer 33 can be formed by forming an insulating film using, for example, CVD or ALD, and then partially removing the insulating film in the thickness direction to expose the upper surface of the conductive oxide layer 32. The insulating layer 33 can be partially removed by RIE or CMP, for example.

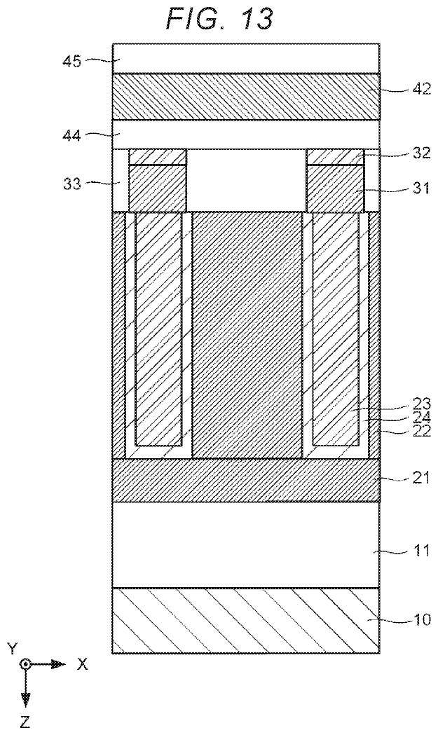

Next, as illustrated in FIG. 13, the insulating layer 44, the conductive layer 42, and the insulating layer 45 are sequentially formed on the conductive oxide layer 32 and the insulating layer 33. The conductive layer 42 can be formed by, for example, forming a conductive film using sputtering or ALD, and then partially removing the conductive film by etching using, for example, a resist mask. The insulating layer 44 and the insulating layer 45 can be formed using CVD or ALD, for example.

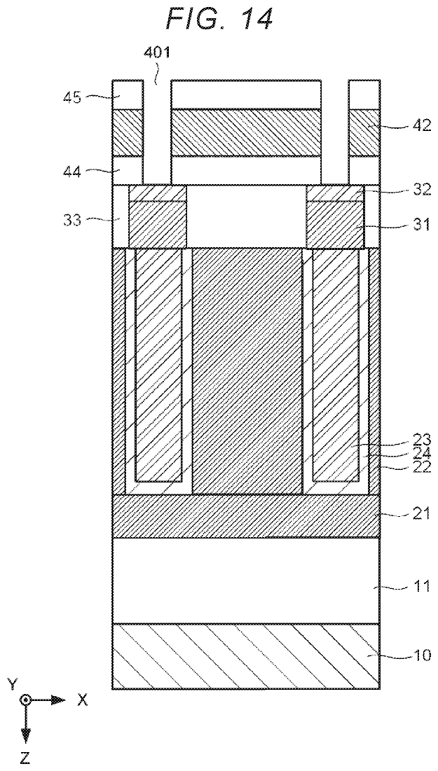

Next, as illustrated in FIG. 14, an opening 401 is formed through the stacked body including the insulating layer 44, the conductive layer 42, and the insulating layer 45 in the Z-axis direction to partially expose the upper surface of the conductive oxide layer 32. The opening 401 can be formed by partially removing the stacked body in the thickness direction, for example, by etching using a resist mask.

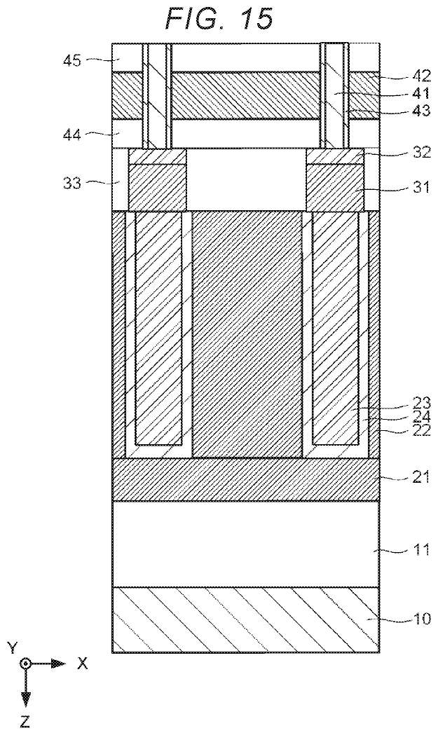

Next, as illustrated in FIG. 15, the insulating film 43 and the oxide semiconductor layer 41 are formed on the inner surface of the opening 401. The insulating film 43 is formed by forming an insulating film in the opening 401 using, for example, CVD or ALD, and then partially removing the insulating film in the thickness direction by RIE to partially expose the upper surface of the conductive oxide layer 32. The oxide semiconductor layer 41 is formed by, for example, forming an oxide semiconductor film on the insulating film 43 by sputtering or ALD, and then partially removing the oxide semiconductor film in the thickness direction by RIE to expose the upper surface of the insulating layer 45.

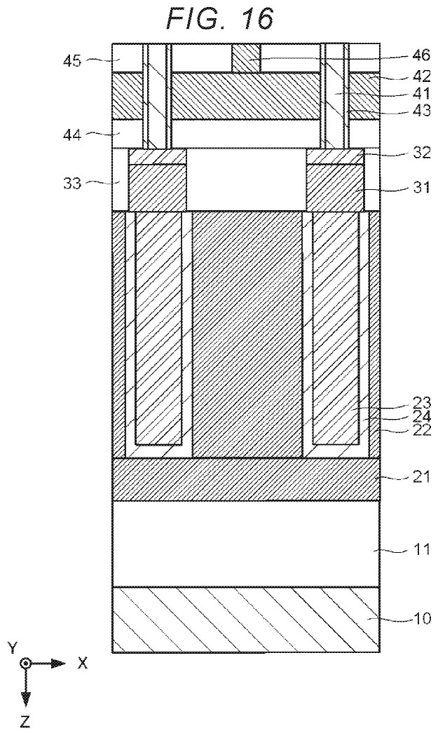

Next, as illustrated in FIG. 16, the conductor 46 is formed on the conductive layer 42. The conductor 46 is formed by, for example, partially removing the insulating layer 45 to form an opening that partially exposes the upper surface of the conductive layer 42, forming a conductive film in the opening, and then partially removing the conductive film in the thickness direction by RIE or CMP to expose the upper surface of the insulating layer 45.

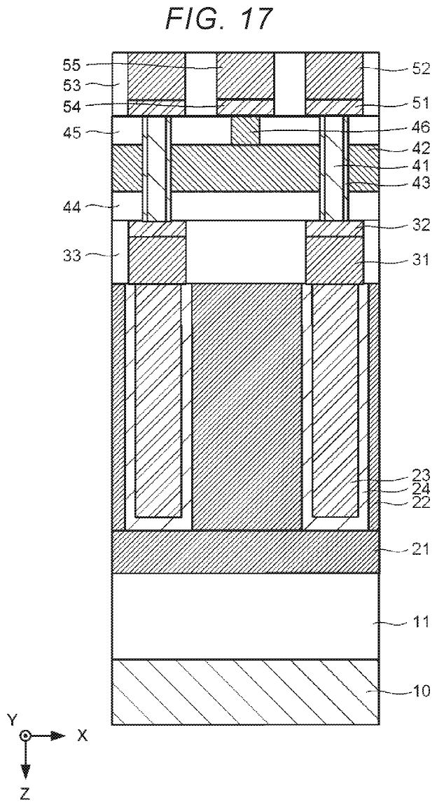

Next, as illustrated in FIG. 17, the conductive oxide layer 51, the conductive layer 52, the insulating layer 53, the conductive oxide layer 54, and the conductive layer 55 are formed. The conductive oxide layer 51, the conductive layer 52, the conductive oxide layer 54, and the conductive layer 55 can be formed in the same process and can be formed by, for example, forming a stacked film using sputtering or ALD, and then partially removing the stacked film by etching using, for example, a resist mask. The insulating layer 53 can be formed by, for example, forming an insulating film on the conductive layer 52, the conductive layer 55, and the insulating layer 45 using CVD or ALD, and then partially removing the insulating film in the thickness direction to expose the upper surface of the conductive layer 52 and the upper surface of the conductive layer 55.

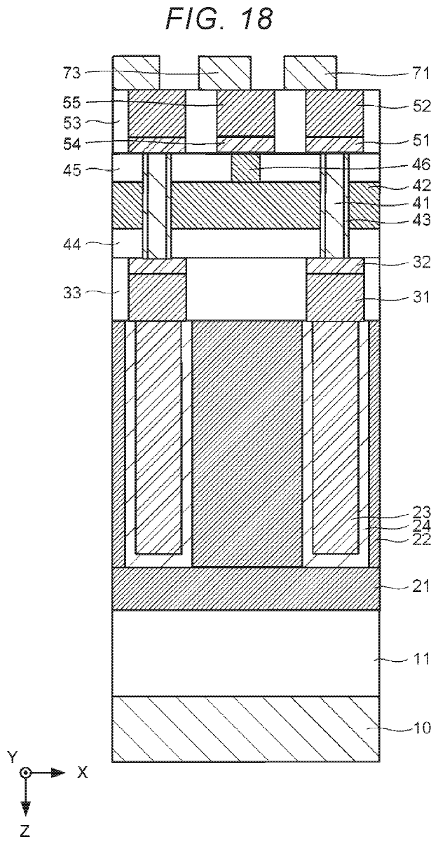

Next, as illustrated in FIG. 18, the conductive layer 71 and the conductive layer 73 are formed. The conductive layer 71 and the conductive layer 73 can be formed in the same process and can be formed by, for example, forming a conductive film using sputtering or ALD, and then partially removing the conductive film by etching using a resist mask, for example.

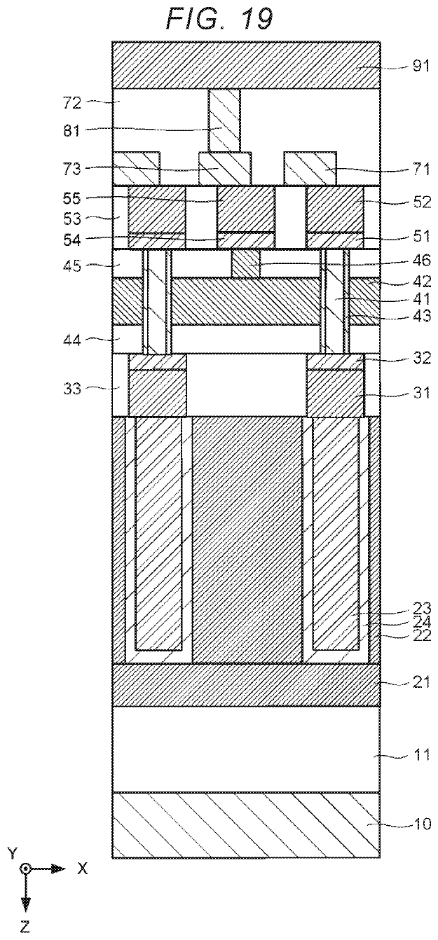

Next, as illustrated in FIG. 19, the insulating layer 72, the conductor 81, and the conductive layer 91 are formed. The insulating layer 72 can be formed using CVD or ALD, for example. The conductor 81 is formed by, for example, partially removing the insulating layer 72 to form an opening that partially exposes the upper surface of the conductive layer 73, forming a conductive film in the opening, and then partially removing the conductive film in the thickness direction by RIE or CMP to expose the upper surface of the insulating layer 72. The conductive layer 91 can be formed by, for example, forming a conductive film on the insulating layer 72 and the conductor 81 using sputtering or ALD, and then partially removing the conductive film by etching using, for example, a resist mask. The above is the description of the example of the manufacturing method of the first structural example.

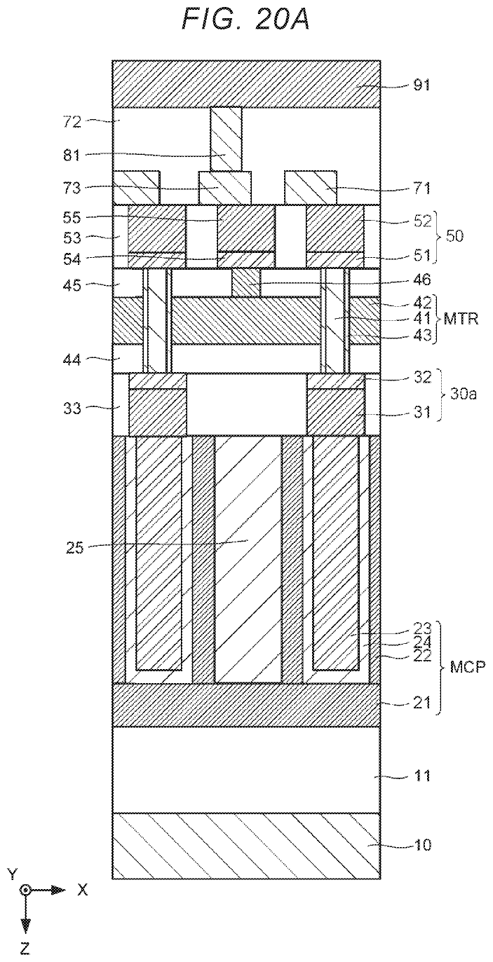

In the first structural example, an insulator 25 may be formed below the conductor 46 as illustrated in FIG. 20A. The insulator 25 is a columnar body extending to penetrate the conductive layer 22 in the Z-axis direction. The insulator 25 is provided between the plurality of memory capacitors MCP. A plurality of insulators 25 may be provided corresponding to the plurality of conductors 46. The insulator 25 comprises, for example, silicon and oxygen or silicon and nitrogen. The insulator 25 can be formed by forming an opening between the plurality of memory capacitors MCP in the process of forming the openings 22a illustrated in FIG. 9, forming an insulating film in the opening using, for example, CVD or ALD, and then partially removing the insulating film in the thickness direction by RIE or CMP to expose the upper surface of the conductive layer 22. By forming the insulator 25, the parasitic capacity between the word line WL and the plate electrode can be reduced.

In the first structural example, as illustrated in FIG. 20B, the memory capacitor MCP and the conductor 30a may be formed below the conductor 46, and an insulator 441 may be formed between the conductor 30a and the conductor 46. The conductor 46 extends in the Z-axis direction in the conductive layer 42 and is connected to the conductive layer 42. The insulator 441 is a columnar body penetrating the insulating layer 44 in the Z-axis direction. The insulator 441 may extend in the conductive layer 42. The insulator 441 may comprise, for example, a material applicable to the insulating layer 44 or a material different from that of the insulating layer 44. In the structural example illustrated in FIG. 20B, the insulator 441 and the conductor 46 can be formed in at least one of the plurality of openings 401 formed over the memory capacitor MCP and the conductor 30a, for example, in the process illustrated in FIG. 14 by using CVD or ALD. The structural example illustrated in FIG. 20B can be formed using the opening 401 and is therefore preferable in that an increase in the number of manufacturing steps can be reduced.

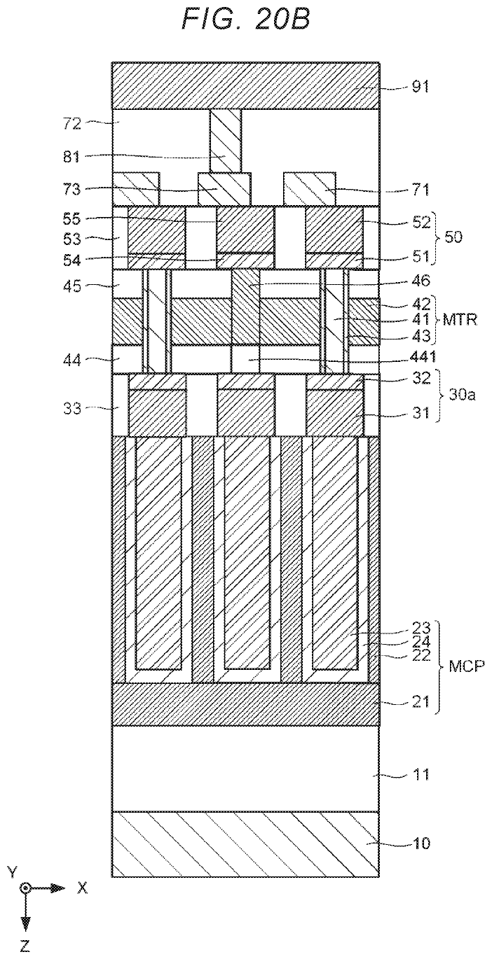

In the first structural example, as illustrated in FIG. 21, instead of the conductive layer 91, a conductive layer 91a and a conductive layer 91b may be provided. FIG. 21 illustrates a part of the X-Y plane. A plurality of conductive layers 91a are provided corresponding to even-numbered word lines WL, for example. The conductive layer 91a is electrically connected to the conductive layer 42 via the conductor 46, the conductor 50b, the conductive layer 73, and the conductor 81, similarly to the memory cell arrays illustrated in FIGS. 4 and 5. A plurality of conductive layers 91b are provided corresponding to odd-numbered word lines WL, for example. The conductive layer 91b is electrically connected to the conductive layer 42 via the conductor 46, the conductor 50b, the conductive layer 73, and the conductor 81, similarly to the memory cell arrays illustrated in FIGS. 4 and 5. The conductive layers 91a and 91b each have a length shorter than the length of conductive layer 91. The conductive layer 91a is connected to, for example, one of a plurality of segment word line drive circuits provided in the row decoder. The conductive layer 91b is connected to, for example, another one of the plurality of segment word line drive circuits provided in the row decoder. A plurality of segment word line drive circuits is provided for one memory cell array. Two or more segment word line drive circuits are connected to the main word line drive circuit. The semiconductor device selects a row of the memory cell array by selecting a segment word line drive circuit with the main word line drive circuit and selecting a word line WL with the selected segment word line drive circuit. For other descriptions of the conductive layer 91a and the conductive layer 91b, the description of the conductive layer 91 can be used as appropriate. By providing the conductive layer 91a and the conductive layer 91b instead of the conductive layer 91, the parasitic capacity between the auxiliary wirings can be made smaller in the X-Y plane than when a plurality of conductive layers 91 are formed.

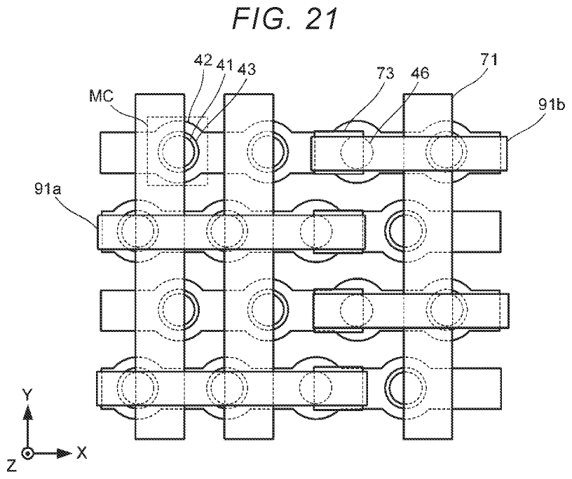

In the first structural example, as illustrated in FIG. 22, the conductive layer 74 may be provided between the conductive layers 71 and 73 on the X-Y plane. FIG. 22 illustrates a part of the X-Y plane. The conductive layer 74 functions as a dummy wiring. The plurality of conductive layers 74 extend parallel to the plurality of conductive layers 71 along the Y-axis direction. The conductive layer 74 can be formed by the same material and the same process as the conductive layer 71. By providing the conductive layer 74, the value of the coupling capacity in the bit line BL can be adjusted.

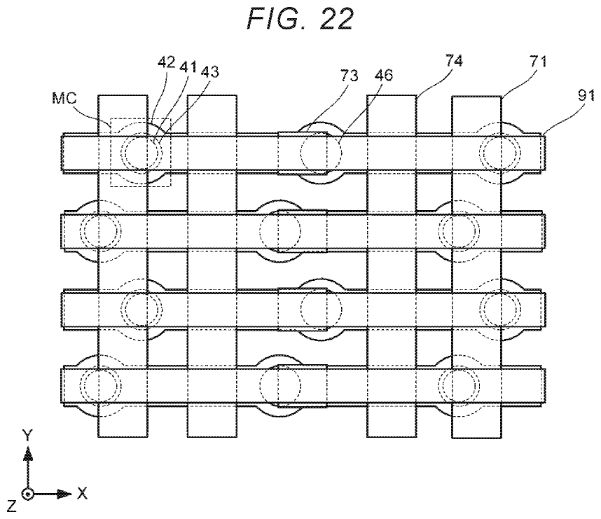

In the first structural example, the conductive layer 42 and the conductive layer 91 may be electrically connected via the conductor 46, the conductor 50b, the conductive layer 73, and the conductor 81 for each of a plurality of bit lines BL. FIG. 23 illustrates a part of the X-Y plane having a plurality of bit lines BL between the plurality of conductors 46 and between the plurality of conductive layers 73 in the X-axis direction. A plurality of bit lines BL is formed between the plurality of conductive layers 73, and the conductive layers 42 and 91 are electrically connected via the conductor 46, the conductor 50b, the conductive layer 73, and the conductor 81 for each of a plurality of bit lines BL to increase the degree of integration of the memory cell MC.

### Modification of First Structural Example

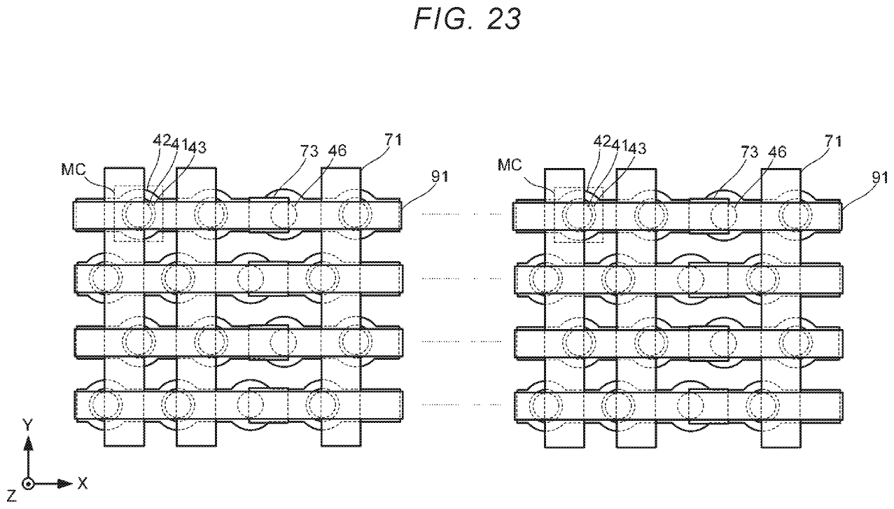

FIG. 24 is a schematic cross-sectional view illustrating a modification of the first structural example of the memory cell array. FIG. 24 illustrates a part of the X-Z cross-section. The memory cell array illustrated in FIG. 24 includes a conductive layer 92 below the conductor 21 and further includes an electrical conductor 26, an insulator 27, a conductive layer 34, a conductive oxide layer 35, and a conductor 47, but does not include the conductor 46, the conductive oxide layer 54, the conductive layer 55, the conductive layer 73, the conductor 81, and the conductive layer 91. In the following, the parts different from FIGS. 2 to 5 will be described, and the descriptions in FIGS. 2 to 5 can be used as appropriate for the other parts.

The conductive layer 92 is provided between the semiconductor substrate 10 and the conductor 21 and extends in the X-axis direction as illustrated in FIG. 24. The conductive layer 92 forms the auxiliary wiring for the word line WL. The conductive layer 92 includes, for example, a material that is applicable to the conductive layer 91. A plurality of conductive layers 92 are provided corresponding to the plurality of conductive layers 42, similarly to the conductive layers 91. An insulating layer 12 is formed between the plurality of conductive layers 92 and between the conductive layers 92 and the conductors 21. The insulating layer 12 comprises, for example, silicon and oxygen or silicon nitrogen.

The electrical conductor 26 penetrates the insulating layer 12, the conductor 21, and the conductive layer 22 in the Z-axis direction and reaches the conductive layer 92. The electrical conductor 26 comprises materials applicable to the conductive layer 42 and the electrical conductor 23, for example. For example, the electrical conductor 26 and the conductive layer 42 may comprise the same material. A plurality of electrical conductors 26 are provided.

The insulator 27 is provided between the insulating layer 12, the conductor 21, and the conductive layer 22, and the electrical conductor 26, for example, in the X-Y plane. The insulator 27 comprises, for example, silicon and oxygen or silicon nitrogen. A material applicable to the insulator 24 may also be included.

The conductive layer 34 is provided over the electrical conductor 26 and electrically connected to the electrical conductor 26. The conductive layer 34 includes, for example, a material applicable to the conductive layer 31.

The conductive oxide layer 35 is provided on the conductive layer 34. The conductive oxide layer 35 comprises, for example, materials applicable to the conductive oxide layer 32.

The conductive layer 34 and the conductive oxide layer 35 form a conductor 30b. A plurality of conductors 30b are provided corresponding to the plurality of electrical conductors 26. The insulating layer 33 is formed between the plurality of conductors 30b and between the conductors 30a and the conductors 30b. In some examples, one of the conductive layer 34 and the conductive oxide layer 35 may not be formed.

The conductor 47 electrically connects the conductive layer 42 and the conductive oxide layer 35. The conductor 47 includes, for example, a material applicable to the conductive layer 42. A plurality of conductors 47 are provided corresponding to the plurality of electrical conductors 26.

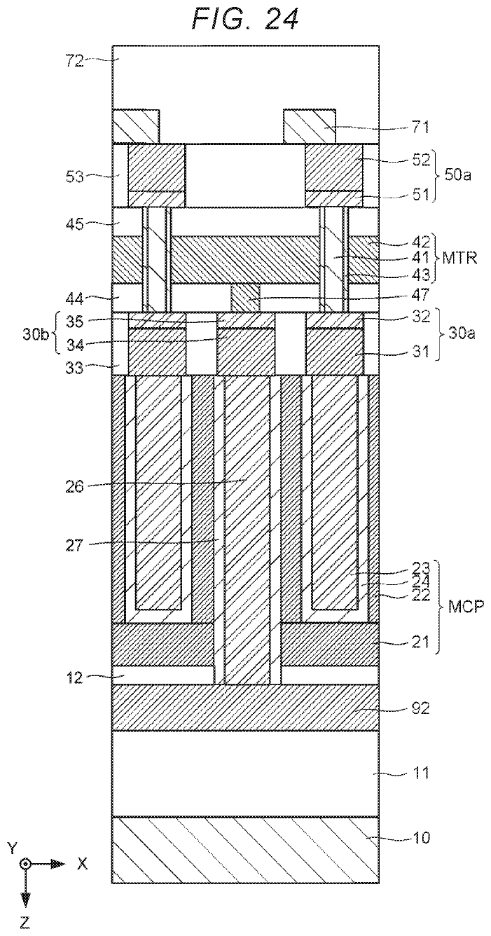

Next, an example of a manufacturing method of the modification of the first structural example will be described with reference to FIGS. 25 to 31. FIGS. 25 to 31 are schematic cross-sectional views illustrating an example of the manufacturing method of the modification of the first structural example. FIGS. 25 to 31 illustrate a part of the X-Z cross section. Here, a manufacturing process from forming the peripheral circuit to forming the memory cell array will be described.

As illustrated in FIG. 25, the conductive layer 92 is formed on the insulating layer 11 above the semiconductor substrate 10 and the insulating layer 12 is formed on the conductive layer 92. The conductive layer 92 can be formed by forming a conductive film on the insulating layer 11 using, for example, sputtering or ALD, and then partially removing the conductive film by etching using a patterned resist mask. The insulating layer 12 can be formed using CVD or ALD, for example.

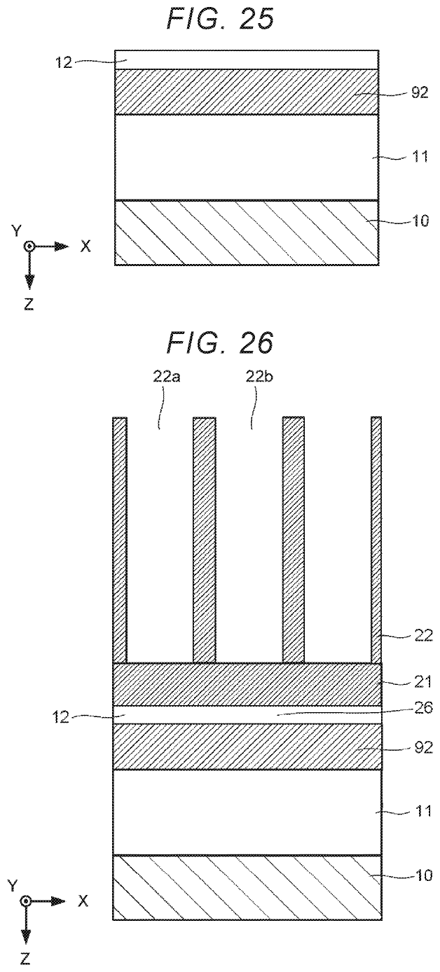

Next, as illustrated in FIG. 26, through processes similar to those of FIGS. 6, 7, 8, and 9, openings 22a are formed, and openings 22b are formed between the plurality of openings 22a. The opening 22b can be formed in the same process as the opening 22a.

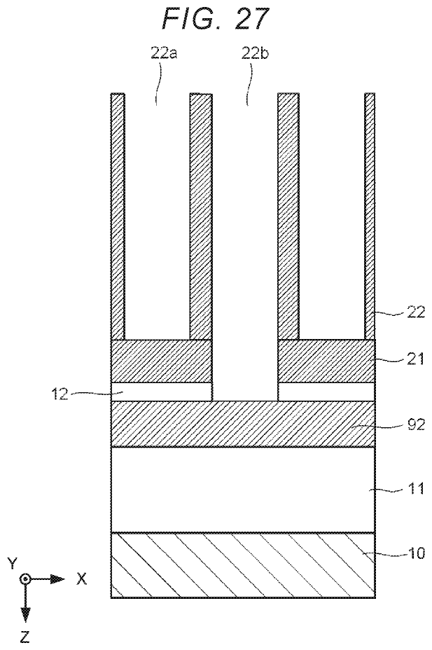

Next, as illustrated in FIG. 27, the conductor 21 and the insulating layer 12 are partially removed at the opening 22b to partially expose the upper surface of the conductive layer 92. For example, the conductor 21 and the insulating layer 12 can be partially removed in the opening 22b by etching using a resist mask. The conductor 21 and the insulating layer 12 may be processed separately by a plurality of etchings.

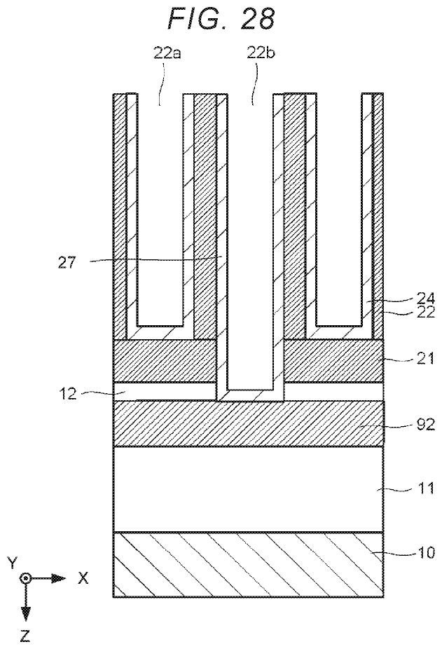

Next, as illustrated in FIG. 28, the insulator 24 is formed in the opening 22a, and the insulator 27 is formed in the opening 22b. The insulator 24 and the insulator 27 can be formed in the same process, and can be formed by, for example, forming an insulating film using CVD or ALD, and then partially removing the insulating film in the thickness direction to expose the upper surface of the conductive layer 22. The insulator 24 and the insulator 27 can be partially removed using, for example, CMP.

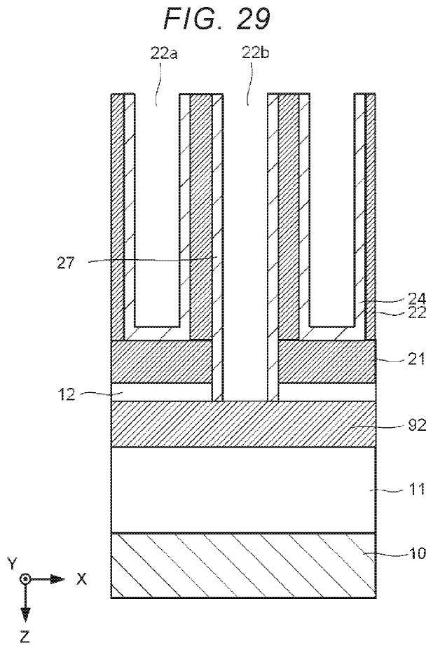

Next, as illustrated in FIG. 29, the insulator 27 is partially removed in the opening 22b to partially expose the upper surface of the conductive layer 92. For example, the insulator 27 can be partially removed in the opening 22b by etching using a patterned resist mask.

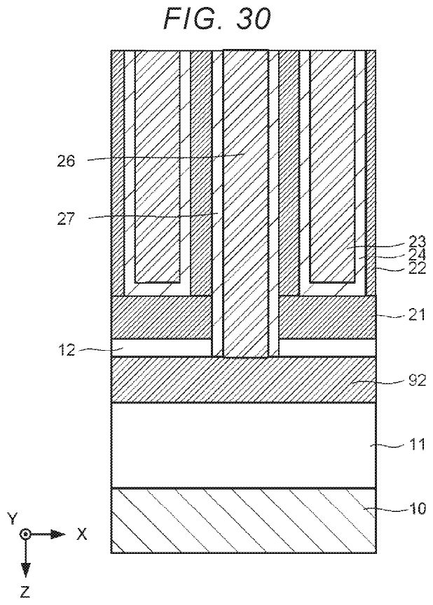

Next, as illustrated in FIG. 30, the electrical conductor 23 is formed on the insulator 24 in the opening 22a, and the electrical conductor 26 is formed on the insulator 27 and the conductive layer 92 in the opening 22b. The electrical conductor 23 and the electrical conductor 26 can be formed by the same process, and are formed by, for example, forming a film using sputtering or ALD, and then partially removing the film in the thickness direction by RIE to expose the upper surface of the conductive layer 22.

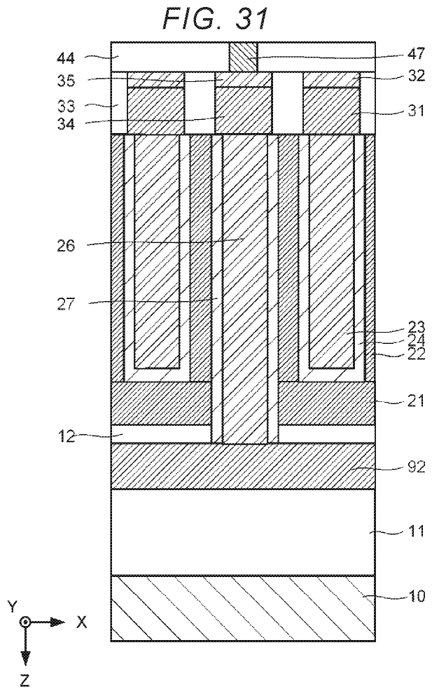

Next, as illustrated in FIG. 31, the conductive layer 31, the conductive oxide layer 32, the conductive layer 34, and the conductive oxide layer 35 are formed in the same processes as in the processes illustrated in FIG. 12. The insulating layer 33 is formed, and the insulating layer 44 and the conductor 47 are formed. The insulating layer 44 and the conductor 47 are formed by forming the insulating layer 44, partially removing, for example, the insulating layer 44 to form an opening that partially exposes the upper surface of the conductive oxide layer 35, and then forming a conductive film in the opening, and then partially removing the conductive film in the thickness direction by RIE or CMP to expose the upper surface of the insulating layer 44.

After that, similarly to the processes illustrated in FIGS. 14, 15, 17, 18, and 19, the oxide semiconductor layer 41, the conductive layer 42, the insulating film 43, the insulating layer 45, the conductive oxide layer 51, the conductive layer 52, the insulating layer 53, the conductive layer 71, and the insulating layer 72 are formed. The above is the description of the example of the manufacturing method of the modification of the first structural example. The process of forming the opening 22b, the insulator 27, and the electrical conductor 26 can be performed separately from the process of forming the opening 22a, the insulator 24, and the electrical conductor 23. Here, the insulators 24 and 27 can be made of different materials, and the electrical conductors 23 and 26 can be made of different materials.

### Second Structural Example of Memory Cell Array

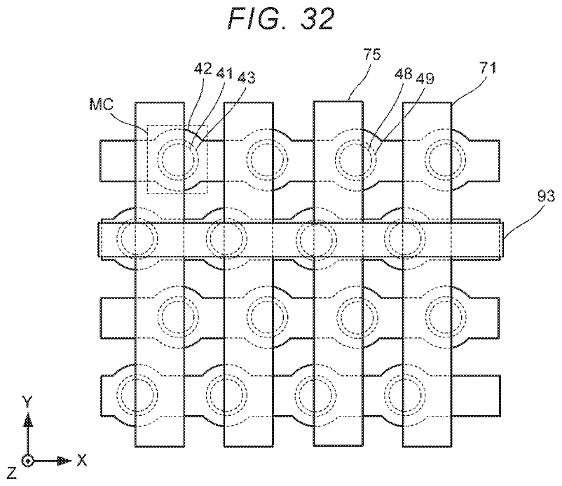

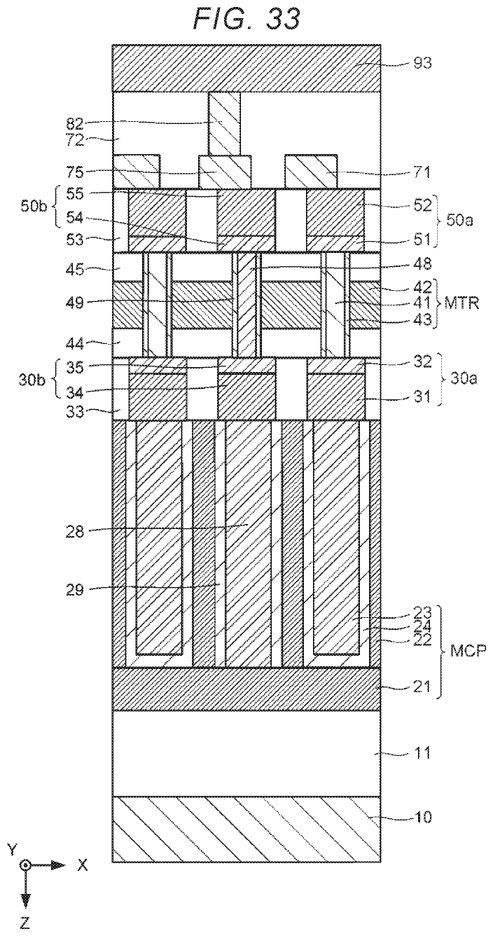

FIG. 32 is a schematic plan view illustrating a second structural example of the memory cell array. FIG. 33 is a schematic cross-sectional view illustrating the second structural example of the memory cell array. FIG. 32 illustrates a part of the X-Y plane. FIG. 33 illustrates a part of the X-Z cross-section. In the following, the parts different from FIGS. 2 to 5 will be described, and the descriptions in FIGS. 2 to 5 can be used as appropriate for the other portions.

The second structural example of the memory cell array further includes an electrical conductor 28, an insulator 29, the conductive layer 34, the conductive oxide layer 35, a conductor 48, an insulating film 49, the conductive oxide layer 54, the conductive layer 55, a conductive layer 75, a conductor 82, and a conductive layer 93, and does not include the conductive layer 73, the conductor 81, and the conductive layer 91. FIG. 32 illustrates the oxide semiconductor layer 41, the conductive layer 42, the insulating film 43, the conductor 48, the insulating film 49, the conductive layer 71, the conductive layer 75, and the conductive layer 93 for convenience, and the illustration of other components is omitted for convenience.

The electrical conductor 28 penetrates the conductive layer 22 in the Z-axis direction and reaches the conductor 21. The electrical conductor 28 comprises, for example, materials applicable to the electrical conductor 23 and the conductive layer 42. A plurality of electrical conductors 28 are provided.

The insulator 29 is provided between the conductive layer 22 and the electrical conductor 28, for example, in the X-Y plane. The insulator 29 comprises, for example, a material applicable to the insulator 24. The insulator 29 may comprise a material different from the material of the insulator 24.

The conductive layer 34 is provided on the electrical conductor 28 and electrically connected to the electrical conductor 28. The conductive layer 34 includes, for example, a material applicable to the conductive layer 31.

The conductive oxide layer 35 is provided on the conductive layer 34. The conductive oxide layer 35 comprises, for example, a material applicable to the conductive oxide layer 32.

The conductive layer 34 and the conductive oxide layer 35 form the conductor 30b. A plurality of conductors 30b are provided corresponding to the plurality of electrical conductors 28. The insulating layer 33 is formed between the plurality of conductors 30b and between the conductors 30a and the conductors 30b. In some examples, one of the conductive layer 34 and the conductive oxide layer 35 may not be formed.

The conductor 48 is, for example, a columnar body extending in the Z-axis direction. The conductor 48 penetrates the conductive layer 42 in the Z-axis direction. The conductor 48 comprises, for example, a material applicable to the conductive layer 42. The conductor 48 may comprise a material different from the material of the conductive layer 42.

The insulating film 49 is provided between the conductor 48 and the conductive layer 42 on the X-Y plane. The insulating film 49 comprises, for example, a material applicable to the insulating film 43, but is not limited thereto and may include a material different from the material provided in the insulating film 43.

The conductive oxide layer 54 is provided over the conductor 48. The conductive oxide layer 54 includes, for example, a material applicable to the conductive oxide layer 51.

The conductive layer 55 is provided on the conductive oxide layer 54 and electrically connected to the conductive oxide layer 54. The conductive layer 55 includes, for example, a material applicable to the conductive layer 52. In some examples, one of the conductive oxide layer 54 and the conductive layer 55 may not be provided.

The conductive oxide layer 54 and the conductive layer 55 form the conductor 50b. A plurality of conductors 50b are provided corresponding to the plurality of conductors 48. The insulating layer 53 is formed between the plurality of conductors 50b and between the conductors 50a and the conductors 50b.

The conductive layer 75 is provided between the plurality of conductive layers 71 in the X-axis direction and extends in the Y-axis direction. The conductive layer 75 overlaps the plurality of conductors 48 and the plurality of conductors 50b along the Y-axis direction when viewed from the Z-axis direction. The conductive layer 75 is connected to the plurality of conductors 48 via a plurality of conductors 50b. The conductive layer 75 is provided in the same layer as the conductive layer 71 and is provided on the conductive layer 55. The conductive layer 75 comprises a material applicable to the conductive layer 71. A plurality of conductive layers 75 may be provided.

The conductor 82 is provided on the conductive layer 75 and extends in the insulating layer 72 in the Z-axis direction. The conductor 82 electrically connects the conductive layer 93 and the conductive layer 75. The conductor 82 comprises a material applicable to the conductor 81, for example. A plurality of conductors 82 may be provided.

The conductive layer 93 is provided on the conductor 82 and the insulating layer 72 and extends in the X-axis direction as illustrated in FIG. 32. The conductive layer 93 forms a power supply line VPL as wiring. The conductive layer 93 comprises a material applicable to the conductive layer 91. At least one conductive layer 93 is provided corresponding to the conductor 21.

As described above, in the second structural example, the conductive layer 93 is provided above the plurality of memory cells MC, the conductor 21 and the conductive layer 93 are electrically connected to each other via the electrical conductor 28, the conductor 30b, the conductor 48, the conductor 50b, the conductive layer 75, and the conductor 82. Thereby, the influence of noise on the plate electrode can be reduced and the load capacity of the plate electrode can be reduced. As a result, it is possible to reduce deterioration in reliability due to miniaturization of the semiconductor device.

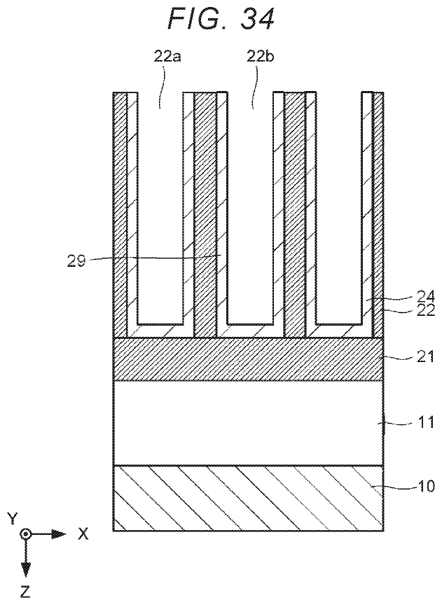

Next, an example of a manufacturing method of the second structural example will be described with reference to FIGS. 34 to 42. FIGS. 34 to 42 are schematic cross-sectional views illustrating an example of the manufacturing method of the second structural example. Here, a manufacturing process from forming the peripheral circuit to forming the memory cell array will be described.

First, through processes similar to those illustrated in FIGS. 6, 7, 8, and 9, the opening 22b is formed together with the opening 22a in the same manner as in the process illustrated in FIG. 26.

Next, as illustrated in FIG. 34, the insulator 24 is formed in the opening 22a, and the insulator 29 is formed in the opening 22b. The insulator 24 and the insulator 29 can be formed in the same process and can be formed by, for example, forming an insulating film using CVD or ALD, and then partially removing the insulating film in the thickness direction to expose the upper surface of the conductive layer 22.

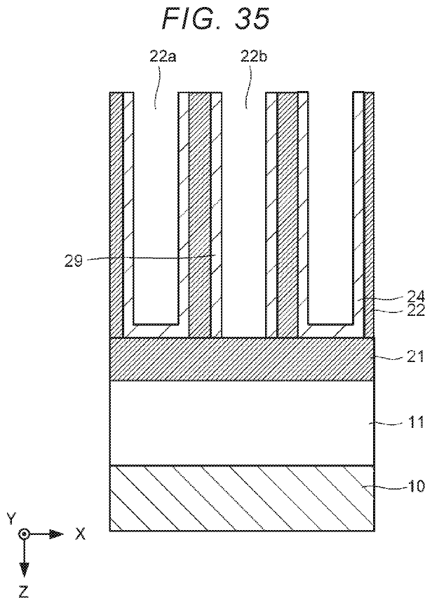

Next, as illustrated in FIG. 35, the insulator 29 is partially removed in the opening 22b to partially expose the upper surface of the conductor 21. For example, the insulator 29 can be partially removed in the opening 22b by etching using a patterned resist mask.

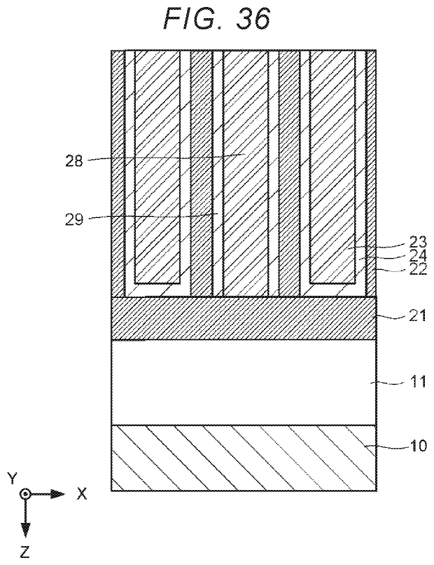

Next, as illustrated in FIG. 36, the electrical conductor 23 is formed on the insulator 24 in the opening 22a, and the electrical conductor 28 is formed on the conductor 21 in the opening 22b. The electrical conductor 23 and the electrical conductor 28 can be formed by the same process, and are formed by forming a film using, for example, sputtering or ALD, and then partially removing the film in the thickness direction by RIE to expose the upper surface of the conductive layer 22.

Next, the conductive layer 31, the conductive oxide layer 32, the conductive layer 34, the conductive oxide layer 35, and the insulating layer 33 are formed in the same manner as in the process illustrated in FIG. 12, and the insulating layer 44, the conductive layer 42, and the insulating layer 45 are sequentially formed on the conductive oxide layer 32, the insulating layer 33, and the conductive oxide layer 35 in the same manner as in the process illustrated in FIG. 13.

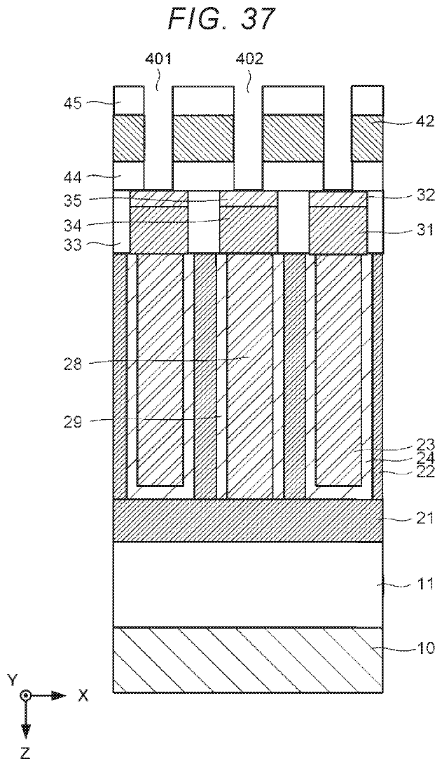

Next, as in the process illustrated in FIG. 14, the opening 401 is formed, and as illustrated in FIG. 37, the opening 402, which penetrates the stacked body including the insulating layer 44, the conductive layer 42, and the insulating layer 45 to reach the conductive oxide layer 35, partially exposes the upper surface of the conductive oxide layer 35. The opening 402 can be formed in the same process as the opening 401, for example.

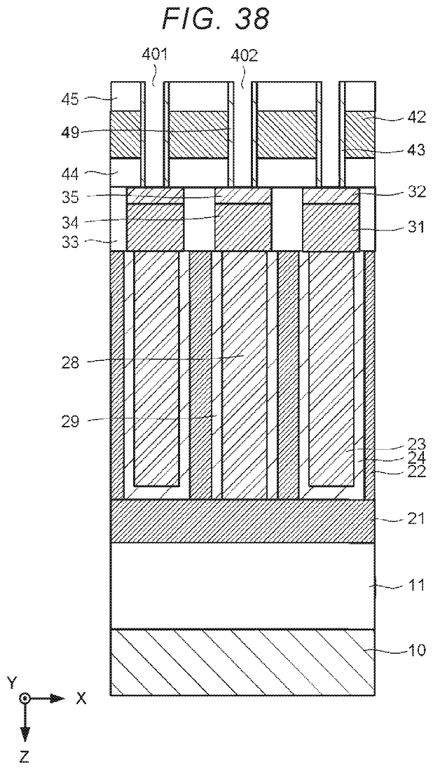

Next, as illustrated in FIG. 38, the insulating film 43 is formed on the inner surface of the opening 401 and the insulating film 49 is formed on the inner surface of the opening 402. The insulating film 43 and the insulating film 49 can be formed in the same process, and are formed by forming an insulating film in the openings 401 and 402 using, for example, CVD or ALD, and then partially removing the insulating film in the thickness direction by RIE to partially expose the upper surface of the conductive oxide layer 32 and the upper surface of the conductive oxide layer 35.

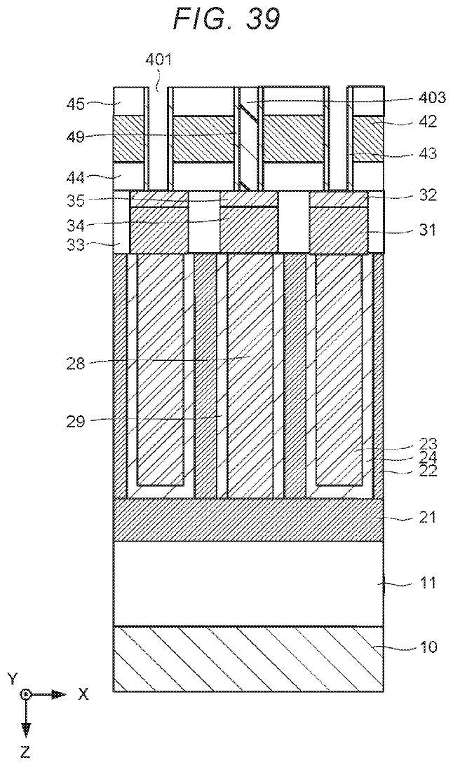

Next, as illustrated in FIG. 39, an insulating layer 403 is formed in the opening 402. The insulating layer 403 is formed by, for example, forming an insulating film by CVD or ALD, then partially removing the insulating film by etching using a patterned resist mask, and then leaving the insulating film in the portion where the conductor 48 is formed. The insulating layer 403 comprises, for example, silicon and nitrogen. The insulating layer 403 can be formed using CVD or ALD, for example.

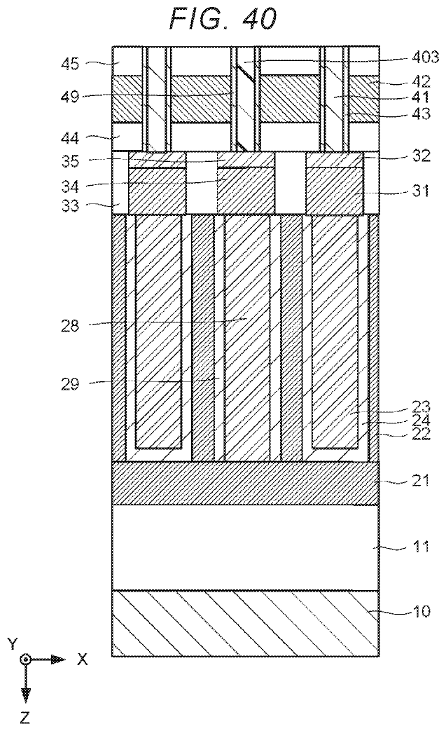

Next, as illustrated in FIG. 40, the oxide semiconductor layer 41 is formed in the opening 401. The oxide semiconductor layer 41 is formed by, for example, forming an oxide semiconductor film on the insulating film 43 by sputtering or ALD and then partially removing the oxide semiconductor film in the thickness direction by RIE to expose the upper surface of the insulating layer 45.

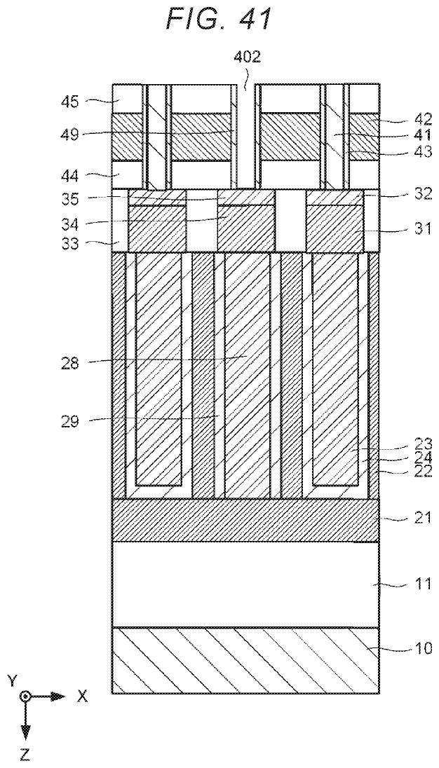

Next, as illustrated in FIG. 41, the insulating layer 403 is removed. The insulating layer 403 can be removed by etching using, for example, a patterned resist mask.

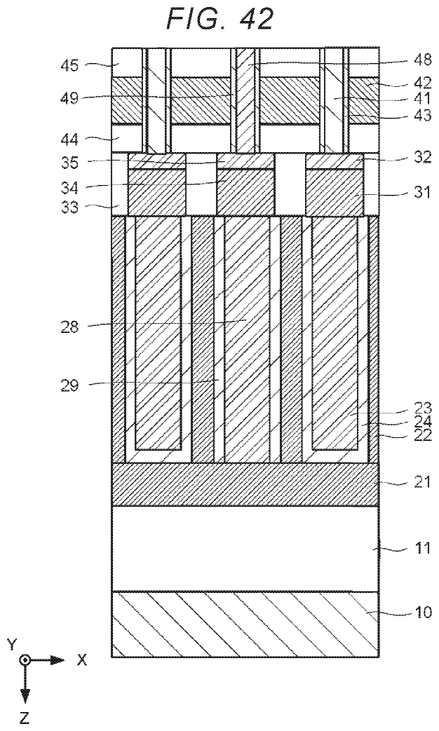

Next, as illustrated in FIG. 42, the conductor 48 is formed in the opening 402. The conductor 48 can be formed by, for example, forming a conductive film using sputtering or ALD, and then partially removing the conductive film by etching using, for example, a patterned resist mask.

After that, by processes similar to the processes illustrated FIGS. 17, 18, and 19, the conductive oxide layer 51, the conductive layer 52, the insulating layer 53, the conductive oxide layer 54, the conductive layer 55, the conductive layer 71, the insulating layer 72, and the conductive layer 75 are formed, and the conductor 82 and the conductive layer 93 are formed. The conductive layer 75 can be formed by the same process as that of the conductive layer 71. The conductor 82 can be formed by a process similar to that of the conductor 81. The conductive layer 93 can be formed by a process similar to that of the conductive layer 91. The above is the description of an example of the manufacturing method of the second structural example. In the above-described process, the insulating layer 403 may be formed in the opening 402 after forming the opening 402 and before forming the insulating film 49. Here, the insulating film 49 can be formed in the opening 402 after the insulating layer 403 is removed, and the material of the insulating film 49 can be different from the material of the insulating film 43. A similar process can also be employed after forming the openings 22a and 22b. Here, the insulator 24 and the insulator 29 can be made of different materials, and the electrical conductor 23 and the electrical conductor 28 can be made of different materials.

The second structural example can be appropriately combined with the first structural example. For example, in the second structural example, the conductive layer 74 functioning as a dummy wiring may be formed between the conductive layer 71 and the conductive layer 75 as illustrated in FIG. 22. In the second structural example, as illustrated in FIG. 23, a plurality of bit lines BL is formed between a plurality of conductive layers 75, and the conductor 21 may be electrically connected to the conductive layer 93 via the electrical conductor 28, the conductor 30b, the conductor 48, the conductor 50b, the conductive layer 75, and the conductor 82.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor substrate;
a capacitor above the semiconductor substrate, the capacitor extending in a first direction and including a first electrode and a second electrode facing the first electrode;
a first conductive layer above the capacitor in the first direction and extending in a second direction intersecting the first direction;
a semiconductor layer penetrating the first conductive layer in the first direction and electrically connected to the first electrode;
a first conductor above or below the first conductive layer in the first direction and electrically connected to the first conductive layer;
a first insulating film between the first conductive layer and the semiconductor layer; and
a second conductive layer extending in the second direction and electrically connected to the first conductive layer via the first conductor.

2. The semiconductor device according to claim 1, wherein the semiconductor layer is an oxide semiconductor.

3. The semiconductor device according to claim 1, wherein the second conductive layer is below the second electrode.

4. The semiconductor device according to claim 3, further comprising:
a first electrical conductor penetrating the second electrode in the first direction and electrically connecting the first conductor and the second conductive layer.

5. The semiconductor device according to claim 4, further comprising:
a second insulating film between the first electrical conductor and the second electrode.

6. The semiconductor device according to claim 4, wherein the first electrical conductor and the first electrode comprise the same material.

7. A semiconductor device, comprising:
a semiconductor substrate;
a capacitor on the semiconductor substrate, the capacitor extending in a first direction and including a first electrode and a second electrode facing the first electrode;
a first conductive layer above the capacitor in the first direction and extending in a second direction intersecting the first direction;
a semiconductor layer penetrating the first conductive layer in the first direction and electrically connected to the first electrode;
a first conductor penetrating the first conductive layer in the first direction and electrically connected to the second electrode;
a first insulating film between the first conductive layer and the semiconductor layer;
a second insulating film between the first conductive layer and the first conductor; and
a second conductive layer electrically connected to the second electrode via the first conductor.

8. The semiconductor device according to claim 7, wherein the semiconductor layer is an oxide semiconductor.

9. The semiconductor device according to claim 7, wherein the first conductor comprises a metal.

10. The semiconductor device according to claim 7, further comprising:
a first electrical conductor below the first conductor and electrically connecting the first conductor and the second electrode.

11. The semiconductor device according to claim 10, wherein the second electrode includes a first portion extending in a first direction and a second portion extending in a direction intersecting the first direction and connected to the first portion.

12. The semiconductor device according to claim 11, further comprising:
a third insulating film between the first electrical conductor and the first portion.

13. The semiconductor device according to claim 10, wherein the first electrical conductor and the first electrode comprise the same material.

14. A semiconductor device, comprising:
a semiconductor substrate;
a first electrode above the semiconductor substrate;
a second electrode extending in a first direction orthogonal to a surface of the semiconductor substrate, the second electrode facing the first electrode across a dielectric layer;
a first conductive layer above the second electrode in the first direction and extending in a second direction intersecting the first direction;
a semiconductor column penetrating the first conductive layer in the first direction and electrically connected to the second electrode;
a first conductor below the first conductive layer in the first direction and electrically connected to the first conductive layer;
a first insulating film between the first conductive layer and the semiconductor column; and
a second conductive layer extending in the second direction and electrically connected to the first conductive layer via the first conductor.

15. The semiconductor device according to claim 14, wherein the semiconductor column is an oxide semiconductor.

16. The semiconductor device according to claim 14, further comprising:
a first electrical conductor penetrating the first electrode in the first direction and electrically connecting the first conductor and the second conductive layer.

17. The semiconductor device according to claim 16, wherein the first electrode includes a first portion extending along the surface of the semiconductor substrate and a second portion extending in the first direction and connected to the first portion.

18. The semiconductor device according to claim 17, further comprising:
a second insulating film between the first electrical conductor and the second portion.

19. The semiconductor device according to claim 18, wherein the second insulating film is also between the first electrical conductor and the first electrode.

20. The semiconductor device according to claim 16, wherein the first electrical conductor and the second electrode comprise the same material.
